(19) United States
(12) Patent Application Publication
(10) Pub. No.: US 2021/0241694 A1
(43) Pub. Date: Aug. 5, 2021

(54) LIGHT-EMITTING CIRCUIT AND ILLUMINING METHOD THEREOF, DRIVE SUB-CIRCUIT, DRIVE CIRCUIT, DISPLAY PANEL AND DISPLAY DEVICE

(71) Applicant: BOE TECHNOLOGY GROUP CO., LTD., Beijing (CN)

(72) Inventors: Mingi CHU, Beijing (CN); Chinlung LIAO, Beijing (CN); Changyen WU, Beijing (CN); Fei YANG, Beijing (CN)

(21) Appl. No.: 17/051,623

(22) PCT Filed: Apr. 27, 2020
(86) PCT No.: PCT/CN2020/087251

§ 371 Date: Oct. 29, 2020

(30) Foreign Application Priority Data
May 5, 2019 (CN) 201910368191.X

(51) Int. Cl. G09G 3/3258; G09G 3/20; G09G 3/3266; G09G 3/3291

(52) U.S. Cl. CPC G09G 3/3258; G09G 3/2003; G09G 3/3266; G09G 2320/0242; G09G 2300/0426; G09G 2300/0443; G09G 3/3291

(57) ABSTRACT

The present disclosure provides a light-emitting circuit, an illumining method thereof, a drive sub-circuit, a drive circuit, a display panel, and a display device. The light-emitting circuit includes N light-emitting layers and N+1 electrode layers, wherein the N light-emitting layers and the N+1 electrode layers are arranged in a laminated manner, and an n^{th} light-emitting layer is provided between an n^{th} electrode layer and an (n+1)^{th} electrode layer; and N is an integer greater than 1, and n is a positive integer less than or equal to N.

### CROSS-REFERENCE TO RELATED APPLICATIONS

The present application is the U.S. national phase of PCT Application No. PCT/CN2020/087251 filed on Apr. 27, 2020, which. claims priority to Chinese Patent Application No. 201910368191.X, filed in China on May 5, 2019, which are incorporated herein by reference in their entities.

### BACKGROUND

OLED (Organic light-emitting Diode) display panels are becoming the next generation of mainstream display panels. In general, a pixel circuit in an OLED display panel includes a light-emitting circuit, a thin film transistor, and a storage capacitor to which a drive voltage corresponding to display data is charged, and the luminance of the light-emitting circuit is controlled by adjusting the magnitude of the drive voltage.

As the requirements of display resolution increase year by year, more pixels need to be disposed on the display panel with the same size, and the aperture ratio, the service life and the driving of the pixel design bring about great challenges. In addition, in the related art, due to the limitation of the process technology, the requirement of minimum spacing exists between sub-pixels with different colors to avoid causing color mixing or other process problems, which results in waste of aperture ratio and reduces the service life of the device.

### SUMMARY

The disclosure provides a light-emitting circuit, including N light-emitting layers and N+1 electrode layers, wherein the N light-emitting layers and the N+1 electrode layers are arranged in a laminated manner, and an n^{th} light-emitting layer is provided between an n^{th} electrode layer and an (n+1)^{th} electrode layer; and

N is an integer greater than 1, and n is a positive integer less than or equal to N.

Optionally, the colors of the N light-emitting layers are different from each other.

Optionally, N is equal to 3;

the first light-emitting layer is a red light-emitting layer, the second light-emitting layer is a green light-emitting layer, and the third light-emitting layer is a blue light-emitting layer;

the first light-emitting layer is a red light-emitting layer, the second light-emitting layer is a blue light-emitting layer, and the third light-emitting layer is a green light-emitting layer;

the first light-emitting layer is a green light-emitting layer, the second light-emitting layer is a red light-emitting layer, and the third light-emitting layer is a blue light-emitting layer;

the first light-emitting layer is a green light-emitting layer, the second light-emitting layer is a blue light-emitting layer, and the third light-emitting layer is a red light-emitting layer;

the first light-emitting layer is a blue light-emitting layer, the second light-emitting layer is a green light-emitting layer, and the third light-emitting layer is a red light-emitting layer; or

the first light-emitting layer is a blue light-emitting layer, the second light-emitting layer is a red light-emitting layer, and the third light-emitting layer is a green light-emitting layer.

Optionally, the N light-emitting layers and the N+1 electrode layers are alternately arranged in a laminated manner.

Optionally, the light-emitting circuit includes three light-emitting layers and four electrode layers;

wherein the three light-emitting layers are respectively a first light-emitting layer, a second light-emitting layer and a third light-emitting layer; the four electrode layers are respectively a first electrode layer, a second electrode layer, a third electrode layer and a fourth electrode layer;

wherein the first electrode layer, the first light-emitting layer and the second electrode layer form a first light-emitting sub-circuit for emitting light of a first color;

the second electrode layer, the second light-emitting layer and the third electrode layer form a second light-emitting sub-circuit for emitting light of a second color; and

the third electrode layer, the third light-emitting layer and the fourth electrode layer form a third light-emitting sub-circuit for emitting light of a third color.

The invention also provides an illumining method of a light-emitting circuit applied to the light-emitting circuit, and the illumining method of the light-emitting circuit includes:

respectively providing corresponding drive voltages for N+1 electrode layers to illumine the light-emitting circuit during a light-emitting stage.

Optionally, the first light-emitting layer is a red light-emitting layer, the second light-emitting layer is a green light-emitting layer, and the third light-emitting layer is a blue light-emitting layer;

the illumining method of the light-emitting circuit includes the steps of: during the light-emitting stage,

controlling the drive voltage supplied to the first electrode layer to be a first high voltage, controlling the drive voltage supplied to the second electrode layer to be a second high voltage, and controlling the drive voltage supplied to the third electrode layer and the drive voltage supplied to the fourth electrode layer to be a low voltage, so that the light-emitting circuit emits yellow light;

controlling the drive voltage supplied to the first electrode layer to be a second high voltage, controlling the drive voltage supplied to the second electrode layer, the drive voltage supplied to the third electrode layer and the drive voltage supplied to the fourth electrode layer to be a low voltage, so that the light-emitting circuit emits red light;

controlling the drive voltage supplied to the second electrode layer to be a second high voltage, controlling the drive voltage supplied to the first electrode layer, the drive voltage supplied to the third electrode layer and the drive voltage supplied to the fourth electrode layer to be a low voltage, so that the light-emitting circuit emits green light;

controlling the drive voltage supplied to the third electrode layer to be a second high voltage, controlling the drive voltage supplied to the first electrode layer, the drive voltage supplied to the second electrode layer and the drive voltage supplied to the fourth electrode layer to be a low voltage, so that the light-emitting circuit emits blue light; or

controlling the drive voltage supplied to the first electrode layer and the drive voltage supplied to the third electrode layer to be a second high voltage, and controlling the drive voltage supplied to the second electrode layer and the drive voltage supplied to the fourth electrode layer to be a low voltage, so that the light-emitting circuit emits fuchsia light.

Optionally, the first light-emitting layer is a red light-emitting layer, the second light-emitting layer is a green light-emitting layer, and the third light-emitting layer is a blue light-emitting layer;

the light-emitting stage includes a plurality of light-emitting sub-stages which are sequentially provided; the light-emitting sub-stage includes a first light-emitting time period and a second light-emitting time period which are sequentially provided; the illumining method of the lighting circuit includes the steps of:

controlling the drive voltage supplied to the first electrode layer and the drive voltage supplied to the fourth electrode layer to be a low voltage during the light-emitting stage; controlling the drive voltage supplied to the second electrode layer to be a second high voltage, and controlling the drive voltage to the third electrode layer to be a low voltage during the first light-emitting time period; controlling the drive voltage supplied to the second electrode layer to be a low voltage and controlling the drive voltage supplied to the third electrode layer to be a second high voltage during the second light-emitting time period so as to control the light-emitting circuit to emit dark green light; or

controlling the drive voltage supplied to the fourth electrode layer to be a low voltage during the light-emitting stage; controlling the drive voltage supplied to the first electrode layer to be a low voltage, controlling the drive voltage supplied to the second electrode layer to be a second high voltage and controlling the drive voltage of the third electrode layer to be a low voltage during the first light-emitting time period; and controlling the drive voltage supplied to the first electrode layer to be a high voltage, controlling the drive voltage supplied to the second electrode layer to be a low voltage, and controlling the drive voltage supplied to the third electrode layer to be a second high voltage during the second light-emitting time period so as to control the light-emitting circuit to emit white light.

The present disclosure also provides a drive sub-circuit for supplying a drive voltage to an n^{th} electrode layer in the above-mentioned light-emitting circuit; and the drive sub-circuit includes a voltage selector and M pixel drive sub-circuits, wherein M is a positive integer;

the m^{th} pixel drive sub-circuit is used for controlling the m^{th} drive voltage to be outputted to the voltage selector under the control of a gate drive signal input by a corresponding gate line and an m^{th} data voltage on an m^{th} data line; m is a positive integer less than or equal to M; and

the voltage selector is used for controlling a drive voltage supplied by one pixel drive sub-circuit or a predetermined drive voltage input by a predetermined drive voltage terminal to be provided to the n^{th} electrode layer under the control of a selection control signal input by a selection control terminal of the voltage selector.

Optionally, the m^{th} pixel drive sub-circuit includes an m^{th} drive module, an m^{th} data writing module and an m^{th} energy storage module,

wherein a control terminal of the m^{th} data writing module is connected with the corresponding gate line, a first terminal of the m^{th} data writing module is connected with the m^{th} data line, a second terminal of the m^{th} data writing module is connected with the control terminal of the m^{th} drive module, and the m^{th} data writing module is used for controlling the m^{th} data voltage to be written into the control terminal of the m^{th} drive module under the control of the gate drive signal;

the m^{th} drive module is used for controlling the m^{th} drive voltage to be outputted to the voltage selector under the control of the potential of the control terminal of the m^{th} drive module; and

the m^{th} energy storage module is connected with the control terminal of the m^{th} drive module for maintaining the potential of the control terminal of the m^{th} drive module.

Optionally, the voltage selector includes M+1 selective switch circuits;

the m^{th} selective switch circuit is used for controlling the m^{th} drive voltage supplied by the m^{th} pixel drive sub-circuit to be provided to the n^{th} electrode layer under the control of the selection control signal input by the selection control terminal; and

the (M+1)^{th} selective switch circuit is used for controlling the predetermined drive voltage input by the predetermined drive voltage terminal to be provided to the n^{th} electrode layer under the control of the selection control signal input by the selection control terminal.

The disclosure also provides a drive circuit including N drive sub-circuits described above;

an n^{th} drive sub-circuit is connected with an n^{th} electrode layer included in a light-emitting circuit for supplying a corresponding drive voltage for the n^{th} electrode layer; and

n is a positive integer less than or equal to N, and N is an integer greater than 1.

Optionally, the drive circuit of the present disclosure further includes a voltage supply unit;

wherein the voltage supply unit is connected with an (N+1)^{th} electrode layer included in the light-emitting circuit for supplying the corresponding drive voltage to the (N+1)^{th} electrode layer.

The present disclosure also provides a display panel including the light-emitting circuit described above.

The present disclosure also provides a display device including the drive circuit described above.

### BRIEF DESCRIPTION OF THE DRAWINGS

FIG. 1 is a structure diagram of a light-emitting circuit according to some embodiments of the present disclosure;

FIG. 2 is a structure diagram of a drive sub-circuit according to some embodiments of the present disclosure;

FIG. 3 is another structure diagram of the drive sub-circuit according to some embodiments of the present disclosure;

FIG. 4 is a circuit diagram of the drive sub-circuit according to some embodiments of the present disclosure;

FIG. 5 is yet another structure diagram of the drive sub-circuit according to some embodiments of the present disclosure;

FIG. 6 is a circuit diagram of some embodiments of a pixel circuit (some embodiments of the pixel circuit include some embodiments of the light-emitting circuit described in this disclosure and some embodiments of the drive circuit described in this disclosure);

FIG. 7A is a timing diagram of the drive voltage connected with E2 and the drive voltage connected with E3 when some embodiments of the pixel circuit display dark green color; and

FIG. 7B is a timing diagram of the drive voltage connected with E1, the drive voltage connected with E2, and the drive voltage connected with E3 when some embodiments of the pixel circuit display white color.

### DETAILED DESCRIPTION

In the following, the technical solutions in the embodiments of the present disclosure will be clearly and completely described with reference to the drawings in the embodiments of the present disclosure. Obviously, the described embodiments are only a part, but not all of the embodiments of the present disclosure. Based on the embodiments of the present disclosure, all other embodiments obtained by a person of ordinary skill in the art without involving any inventive effort are within the scope of the present disclosure.

The transistors used in all embodiments of the present disclosure may be triodes, thin film transistors or field effect transistors or other devices having the same characteristics. In some embodiments of the present disclosure, one of the electrodes is referred to as a first electrode and the other electrode is referred to as the second electrode in order to distinguish the two electrodes of the transistor other than the control electrode.

In actual operation, when the transistor is a triode, the control electrode can be a base electrode, the first electrode can be a collector electrode, and the second electrode can be an emitter electrode. Optionally, the control electrode may be a base electrode, the first electrode may be an emitter electrode, and the second electrode may be a collector electrode.

In actual operation, when the transistor is a thin film transistor (TFT) or a field effect transistor (FET), the control electrode can be a gate electrode, the first electrode can be a drain electrode, and the second electrode can be a source electrode. Optionally, the control electrode may be a gate electrode, the first electrode may be a source electrode, and the second electrode may be a drain electrode.

The light-emitting circuit includes N light-emitting layers and N+1 electrode layers, wherein the N light-emitting layers and the N+1 electrode layers are arranged in a laminated manner, and an n^{th} light-emitting layer is provided between an n^{th} electrode layer and an (n+1)^{th} electrode layer; and

N is an integer greater than 1, and n is a positive integer less than or equal to N.

According to some embodiments of the present disclosure, the light-emitting circuit includes a plurality of light-emitting layers, the light-emitting layers of various colors can be integrated into one light-emitting circuit, and the luminance of the n^{th} light-emitting layer can be controlled by controlling the voltage of the n^{th} electrode layer and the voltage of the (n+1)^{th} electrode layer, so that a single light-emitting circuit can realize full-color display.

In some embodiments of the present disclosure, the light-emitting layer may be made of an organic light-emitting material, but is not limited thereto.

In some embodiments of the present disclosure, the electrode layer may be made of Indium Tin Oxide (ITO), or the electrode layer may be made of a more conductive metal or metal compound, but is not limited thereto.

In the light-emitting circuit according to some embodiments of the present disclosure, there is no need for a minimum space between adjacent light-emitting layers, and the minimum space limit between adjacent sub-pixels of the related art is eliminated, so that the light-emitting area can be increased, and the lifetime of the light-emitting circuit can be prolonged.

When the pixel includes the light-emitting circuit of some embodiments of the present disclosure, various colors can be integrated into a single pixel, and thus there is no concept of sub-pixels. Each pixel has a full-color display function, the purpose of displaying various colors by a single pixel is achieved, the pixel aperture ratio is effectively improved in a limited space, and a high-resolution design can be achieved.

Specifically, the colors of the N light-emitting layers may be different from each other, but are not limited thereto.

Optionally, N may be equal to 3;

the first light-emitting layer is a red light-emitting layer, the second light-emitting layer is a green light-emitting layer, and the third light-emitting layer is a blue light-emitting layer;

the first light-emitting layer is a red light-emitting layer, the second light-emitting layer is a blue light-emitting layer, and the third light-emitting layer is a green light-emitting layer;

the first light-emitting layer is a green light-emitting layer, the second light-emitting layer is a red light-emitting layer, and the third light-emitting layer is a blue light-emitting layer;

the first light-emitting layer is a green light-emitting layer, the second light-emitting layer is a blue light-emitting layer, and the third light-emitting layer is a red light-emitting layer;

the first light-emitting layer is a blue light-emitting layer, the second light-emitting layer is a green light-emitting layer, and the third light-emitting layer is a red light-emitting layer; or

the first light-emitting layer is a blue light-emitting layer, the second light-emitting layer is a red light-emitting layer, and the third light-emitting layer is a green light-emitting layer.

In actual operation, N is not limited to equal 3. For example, N may be equal to 4, and each light-emitting layer may be one of, but not limited to, a red light-emitting layer, a green light-emitting layer, a blue light-emitting layer, and a white light-emitting layer.

The light-emitting circuit, the drive sub-circuit, the drive circuit and the display device according to the disclosure include a plurality of light-emitting layers, the light-emitting layers of various colors can be integrated into one light-emitting circuit, and the luminance of the n^{th} light-emitting layer can be controlled by controlling the voltage of the n^{th} electrode layer and the voltage of the (N+1)^{th} electrode layer, so that a single light-emitting circuit can realize full-color display. According to the light-emitting circuit of an embodiment of the disclosure, there is no need for a minimum space between adjacent light-emitting layers, and the minimum space limit between adjacent sub-pixels of the related art is eliminated, so that the light-emitting area can be increased, the service life of the light-emitting circuit is prolonged, more pixels can be provided under the same size, and the aperture ratio of a display panel in a display device is improved.

As shown in FIG. 1, a light-emitting circuit according to some embodiments of the present disclosure may include a first electrode layer E1, a first light-emitting layer EL1, a second electrode layer E2, a second light-emitting layer EL2, a third electrode layer E3, a third light-emitting layer EL3, and a fourth electrode layer E4 arranged in a laminated manner;

the first light-emitting layer EL1 is provided between the first electrode layer E1 and the second electrode layer E2;

the second light-emitting layer EL2 is provided between the second electrode layer E2 and the third electrode layer E3;

the third light-emitting layer EL3 is provided between the third electrode layer E3 and the fourth electrode layer E4; and

the first light-emitting layer EL1 is a red light-emitting layer, the second light-emitting layer EL2 is a green light-emitting layer, and the third light-emitting layer EL3 is a blue light-emitting layer.

In the embodiment of the light-emitting circuit shown in FIG. 1, the luminance of light-emitting layers of various color is adjusted by changing the voltage of each electrode layer.

The embodiment of the light-emitting circuit shown in FIG. 1 may be an Organic Light-Emitting Diode (OLED) light-emitting circuit.

In an embodiment of the light-emitting circuit shown in FIG. 1, E1, EL1, and E2 constitute a red light-emitting sub-unit, the E2, EL2, and E3 constitute a green light-emitting sub-unit, and the E3, EL3, and E4 constitute a blue light-emitting sub-unit. A light emission drive voltage between each color light-emitting sub-unit, which is a voltage difference between an anode layer and a cathode layer included in each color light-emitting sub-unit, has a correlation. For example, the second electrode layer E2 may be a cathode layer of the red light-emitting sub-unit or an anode layer of the green light-emitting sub-unit.

Also, in an embodiment of the light-emitting circuit shown in FIG. 1, E1 can be an anode layer of the red light-emitting sub-unit, E3 can be a cathode layer of the green light-emitting sub-unit or an anode layer of the blue light-emitting sub-unit; and E4 may be the cathode layer of the blue light-emitting sub-unit.

When the pixel in the display panel adopts the light-emitting circuit of some embodiments of the present disclosure as shown in FIG. 1, the horizontal resolution can be improved by three times under the same process limitation.

The light-emitting circuit, the drive sub-circuit, the drive circuit and the display device according to the disclosure include a plurality of light-emitting layers, the light-emitting layers of various colors can be integrated into one light-emitting circuit, and the luminance of the n^{th} light-emitting layer can be controlled by controlling the voltage of the n^{th} electrode layer and the voltage of the (N+1)^{th} electrode layer, so that a single light-emitting circuit can realize full-color display. According to the light-emitting circuit of an embodiment of the disclosure, there is no need for a minimum space between adjacent light-emitting layers, and the minimum space limit between adjacent sub-pixels of the related art is eliminated, so that the light-emitting area can be increased, the service life of the light-emitting circuit is prolonged, more pixels can be provided under the same size, and the aperture ratio of a display panel in a display device is improved.

The disclosure discloses an illumining method of a lighting circuit according to some embodiments applied to the lighting circuit, and the illumining method of the light-emitting circuit includes:

respectively providing corresponding drive voltages for N+1 electrode layers to illumine the light-emitting circuit during a light-emitting stage.

According to some embodiments of the present disclosure, the illumining method of the light-emitting circuit, the luminance of the n^{th} light-emitting layer can be controlled by controlling the voltage of the n^{th} electrode layer and the voltage of the (n+1)^{th} electrode layer, so that a single light-emitting circuit can realize full-color display.

Specifically, the first light-emitting layer can be a red light-emitting layer, the second light-emitting layer can be a green light-emitting layer, and the third light-emitting layer can be a blue light-emitting layer;

the illumining method of the light-emitting circuit may include the steps of: during the light-emitting stage,

controlling the drive voltage supplied to the first electrode layer to be a first high voltage, controlling the drive voltage supplied to the second electrode layer to be a second high voltage, and controlling the drive voltage supplied to the third electrode layer and the drive voltage supplied to the fourth electrode layer to be a low voltage, so that the light-emitting circuit emits yellow light;

controlling the drive voltage supplied to the first electrode layer to be a second high voltage, controlling the drive voltage supplied to the second electrode layer, the drive voltage supplied to the third electrode layer and the drive voltage supplied to the fourth electrode layer to be a low voltage, so that the light-emitting circuit emits red light;

controlling the drive voltage supplied to the second electrode layer to be a second high voltage, controlling the drive voltage supplied to the first electrode layer, the drive voltage supplied to the third electrode layer and the drive voltage supplied to the fourth electrode layer to be a low voltage, so that the light-emitting circuit emits green light;

controlling the drive voltage supplied to the third electrode layer to be a second high voltage, controlling the drive voltage supplied to the first electrode layer, the drive voltage supplied to the second electrode layer and the drive voltage supplied to the fourth electrode layer to be a low voltage, so that the light-emitting circuit emits blue light; or

controlling the drive voltage supplied to the first electrode layer and the drive voltage supplied to the third electrode layer to be a second high voltage, and controlling the drive voltage supplied to the second electrode layer and the drive voltage supplied to the fourth electrode layer to be a low voltage, so that the light-emitting circuit emits fuchsia light.

Optionally, the second high voltage may be less than the first high voltage, but not limited thereto.

Optionally, during a light-emitting stage, when red light is displayed, the drive voltage supplied to the first electrode layer is required to be controlled to be a second high voltage; when green light is displayed, the drive voltage supplied to the second electrode layer is required to be controlled to be a second high voltage; when blue light is displayed, the drive voltage supplied to the third electrode layer is required to be controlled to be a second high voltage; and when yellow light is displayed, the drive voltage supplied to the first electrode layer is required to be controlled to be a first high voltage, and the drive voltage supplied to the second electrode layer is required to be controlled to be a second high voltage.

Specifically, the first light-emitting layer can be a red light-emitting layer, the second light-emitting layer can be a green light-emitting layer, and the third light-emitting layer can be a blue light-emitting layer;

the light-emitting stage includes a plurality of light-emitting sub-stages which are sequentially provided; the light-emitting sub-stage includes a first light-emitting time period and a second light-emitting time period which are sequentially provided; the illumining method of the lighting circuit includes the steps of:

controlling the drive voltage supplied to the first electrode layer and the drive voltage supplied to the fourth electrode layer to be a low voltage during the light-emitting stage; controlling the drive voltage supplied to the second electrode layer to be a second high voltage, and controlling the drive voltage to the third electrode layer to be a low voltage during the first light-emitting time period; controlling the drive voltage supplied to the second electrode layer to be a low voltage and controlling the drive voltage supplied to the third electrode layer to be a second high voltage during the second light-emitting time period so as to control the light-emitting circuit to emit dark green light; or

controlling the drive voltage supplied to the fourth electrode layer to be a low voltage during the light-emitting stage; controlling the drive voltage supplied to the first electrode layer to be a low voltage, controlling the drive voltage supplied to the second electrode layer to be a second high voltage and controlling the drive voltage of the third electrode layer to be a low voltage during the first light-emitting time period; and controlling the drive voltage supplied to the first electrode layer to be a high voltage, controlling the drive voltage supplied to the second electrode layer to be a low voltage, and controlling the drive voltage supplied to the third electrode layer to be a second high voltage during the second light-emitting time period so as to control the light-emitting circuit to emit white light.

Optionally, the light-emitting stage may include a plurality of light-emitting sub-stages which are sequentially provided, and the light-emitting sub-stages may include a first light-emitting time period and a second light-emitting time period which are sequentially provided;

when dark green light is displayed, green light is emitted in the first light-emitting time period, and blue light is emitted in the second light-emitting time period, so that dark green light is emitted by light mixing during the light-emitting stage;

when white is displayed, green light is emitted in the first light-emitting period, and red and blue light are emitted in the second period, so that white light is emitted by light mixing during the light-emitting stage.

According to the illumining method of the light-emitting circuit, the drive circuit and the display device according to the disclosure include a plurality of light-emitting layers, the light-emitting layers of various colors can be integrated into one light-emitting circuit, and the luminance of the n^{th} light-emitting layer can be controlled by controlling the voltage of the n^{th} electrode layer and the voltage of the (N+1)^{th} electrode layer, so that a single light-emitting circuit can realize full-color display. According to the light-emitting circuit of an embodiment of the disclosure, there is no need for a minimum space between adjacent light-emitting layers, and the minimum space limit between adjacent sub-pixels of the related art is eliminated, so that the light-emitting area can be increased, the service life of the light-emitting circuit is prolonged, more pixels can be provided under the same size, and the aperture ratio of a display panel in a display device is improved.

The drive sub-circuit according to some embodiments of the present disclosure is used for supplying a drive voltage to an n^{th} electrode layer in the above-mentioned light-emitting circuit; and the drive sub-circuit includes a voltage selector and M pixel drive sub-circuits, wherein M is a positive integer;

the m^{th} pixel drive sub-circuit is used for controlling the m^{th} drive voltage to be outputted to the voltage selector under the control of a gate drive signal input by a corresponding gate line and an m^{th} data voltage on an m^{th} data line; m is a positive integer less than or equal to M; and

the voltage selector is used for controlling a drive voltage supplied by one pixel drive sub-circuit or a predetermined drive voltage input by a predetermined drive voltage terminal to be provided to the n^{th} electrode layer under the control of a selection control signal input by a selection control terminal of the voltage selector.

According to some embodiments of the present disclosure, the drive sub-circuit includes a voltage selector and M pixel drive sub-circuits, each pixel drive sub-circuit provides a different drive voltage, and the voltage selector selects and provides a drive voltage supplied by one pixel drive sub-circuit or a predetermined drive voltage to the n^{th} electrode layer under the control of a selection control signal.

Optionally, the value of M can be selected according to the actual situation.

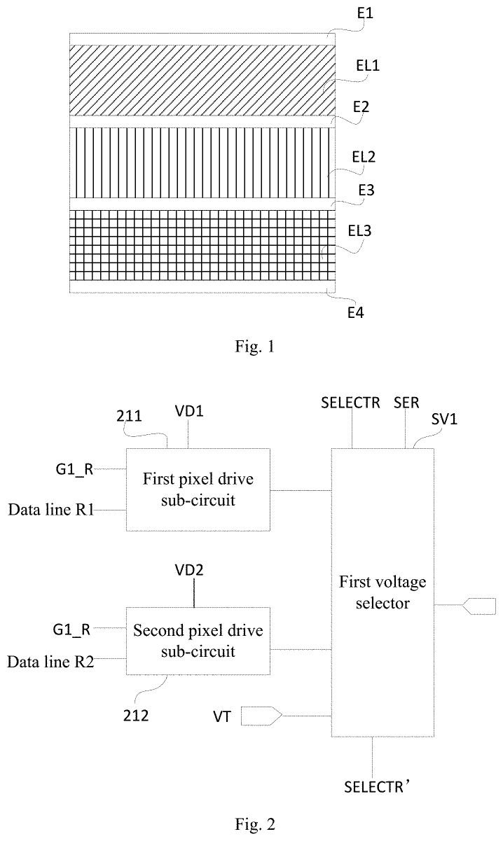

As shown in FIG. 2, the drive sub-circuit according to some embodiments of the present disclosure is used to provide a drive voltage for a first electrode layer in the light-emitting circuit of FIG. 1; M may be equal to 2;

as shown in FIG. 2, the drive sub-circuit according to some embodiments of the present disclosure may include a first pixel drive sub-circuit 211, a second pixel drive sub-circuit 212, and a first voltage selector SV1;

the first pixel drive sub-circuit 211 is respectively connected with a first gate line G1_R, a first data line Dataline R1 and the first voltage selector SV1 for controlling a first drive voltage VD1 to be outputted to the first voltage selector SV1 under the control of a gate drive signal input by the first gate line G1_R and a first red data voltage on the first data line Dataline R1;

the second pixel drive sub-circuit 212 is respectively connected with a first gate line G1_R, a second data line Dataline R2 and the first voltage selector SV1 for controlling a second drive voltage VD2 to be outputted to the first voltage selector SV1 under the control of a gate drive signal input by the first gate line G1_R and a second red data voltage on the second data line Dataline R2;

the selection control terminal of the first voltage selector SV1 includes a first red selection control terminal SELECTR, a second red selection control terminal SELECTR′ and a third red selection control terminal SER;

the first voltage selector SV1 is used for controlling a first drive voltage VD1, a second drive voltage VD2 or a predetermined drive voltage input by the predetermined drive voltage terminal VT to be written into the first electrode layer under the control of a first red selection control signal input by the first red selection control terminal SELECTR, a second red selection control signal input by the second red selection control terminal SELECTR′ and a third red selection control signal input by the third red selection control terminal SER.

In the embodiment shown in FIG. 2, VD1 may be a first high voltage V_HIGH, VD2 may be a second high voltage V_Middle, V_HIGH and V_Middle may both be high voltages, and V_HIGH may be greater than V_Middle, but not limited thereto. For example, V_HIGH may be greater than or equal to 32 V and less than or equal to 48 V, V_Middle may be greater than or equal to 16V and less than 32V, but not limited thereto.

In an embodiment shown in FIG. 2, the predetermined drive voltage terminal VT may be a ground terminal, or the predetermined drive voltage may be a negative voltage, but is not limited thereto.

Specifically, the m^{th} pixel drive sub-circuit may include an m^{th} drive module, an m^{th} data writing module and an m^{th} energy storage module,

wherein a control terminal of the m^{th} data writing module is connected with the corresponding gate line, a first terminal of the m^{th} data writing module is connected with the m^{th} data line, a second terminal of the m^{th} data writing module is connected with the control terminal of the m^{th} drive module, and the m^{th} data writing module is used for controlling the m^{th} data voltage to be written into the control terminal of the m^{th} drive module under the control of the gate drive signal;

the m^{th} drive module is used for controlling the m^{th} drive voltage to be outputted to the voltage selector under the control of the potential of the control terminal of the m^{th} drive module; and

the m^{th} energy storage module is connected with the control terminal of the m^{th} drive module for maintaining the potential of the control terminal of the m^{th} drive module.

Optionally, the m^{th} pixel drive sub-circuit may include an m^{th} drive module, an m^{th} data writing module, and an m^{th} energy storage module to provide a corresponding drive voltage to the voltage selector.

Specifically, the m^{th} drive module can include an m^{th} drive transistor, the m^{th} data writing module can include an m^{th} data writing transistor, and the m^{th} energy storage module can include an m^{th} storage capacitor;

a control electrode of the m^{th} data writing transistor is connected with a corresponding gate line, a first electrode of the m^{th} data writing transistor is connected with the m^{th} data line, and a second electrode of the m^{th} data writing transistor is connected with a control electrode of the m^{th} drive transistor;

a first electrode of the m^{th} drive transistor is connected with an m^{th} drive voltage terminal, and a second electrode of the m^{th} drive transistor is connected with the voltage selector; and the m^{th} drive voltage end is used for inputting an m^{th} drive voltage;

a first terminal of the m^{th} storage capacitor is connected with the control electrode of the m^{th} drive transistor, and the second terminal of the m^{th} storage capacitor is connected with the second electrode of the m^{th} drive transistor.

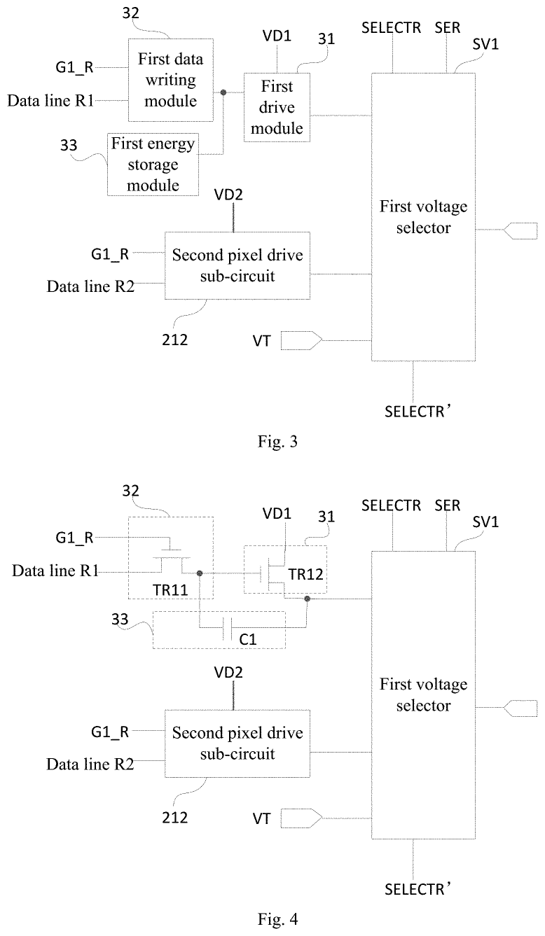

When m is equal to 1, as shown in FIG. 3, the first pixel drive sub-circuit can include a first drive module 31, a first data writing module 32 and a first energy storage module 33,

wherein the control terminal of the first data writing module 32 is connected with a first gate line G1_R, a first terminal of the first data writing module 32 is connected with the first data line Dataline R1, and a second terminal of the first data writing module 32 is connected with a control terminal of the first drive module 31; the first data writing module 32 is used for controlling a first red data voltage VDATA_RH on the first data line Dataline R1 to be written into the control terminal of the first drive module 31 under the control of a gate drive signal input by the first gate line G1_R;

the first drive module 31 is used for controlling the first drive voltage VD1 to be outputted to the first voltage selector SV1 under the control of the potential of the control terminal of the first drive module 31; and

the first energy storage module 33 is connected with the control terminal of the first drive module 31 for maintaining the potential of the control terminal of the first drive module 31.

In operation of an embodiment of the first pixel drive sub-circuit, as shown in FIG. 3, the first data writing module 32 writes VDATA_RH to a control terminal of the first drive module 31 under the control of a gate drive signal input by G1_R, and the first drive module 31 controls the output of VD1 to the first voltage selector SV1 under the control of the potential of the control terminal of the first drive module 31.

As shown in FIG. 4, the first drive module 31 may include a first data writing transistor TR11, a first drive transistor TR12 and a first storage capacitor C1, on the basis of the embodiment of the first pixel drive sub-circuit shown in FIG. 3;

a gate electrode of the TR11 is connected with the first gate line G1_R, a drain electrode of the TR11 is connected with the first data line Dataline R1, and the source electrode of the TR11 is connected with the gate electrode of the TR12;

a drain electrode of the TR12 is connected with a first drive voltage VD1, and the source electrode of the TR12 is connected with the first voltage selector SV1; and

a first terminal of C1 is connected with the gate electrode of the TR12, and a second terminal of C1 is connected with the source electrode of the TR12.

In an embodiment of the first pixel drive sub-circuit shown in FIGS. 4, TR11 and TR12 are both N-type thin film transistors, but are not limited thereto.

In operation of an embodiment of the first pixel drive sub-circuit, as shown in FIG. 4, when G1_R inputs a high-level signal, TR11 is turned on to write a first red data voltage VDATA_RH on Dataline R1 to the gate electrode of TR12; and when VDATA_RH is high level, the TR12 is turned on to output VD1 to the first voltage selector SV1.

Specifically, the voltage selector can include M+1 selective switch circuits;

the m^{th} selective switch circuit is used for controlling the M^{th} drive voltage supplied by the m^{th} pixel drive sub-circuit to be provided to the n^{th} electrode layer under the control of the selection control signal input by the selection control terminal; and

the (M+1)^{th} selective switch circuit is used for controlling the predetermined drive voltage input by the predetermined drive voltage terminal to be provided to the n^{th} electrode layer under the control of the selection control signal input by the selection control terminal.

In some embodiments of the present disclosure, the voltage selector may include M+1 selective switch circuits, an M^{th} selective switch circuit controls an m^{th} drive voltage supplied to an n^{th} electrode layer under the control of the selection control signal, and an (M+1)^{th} selective switch circuit controls a predetermined drive voltage supplied to an n^{th} electrode layer under the control of the selection control signal.

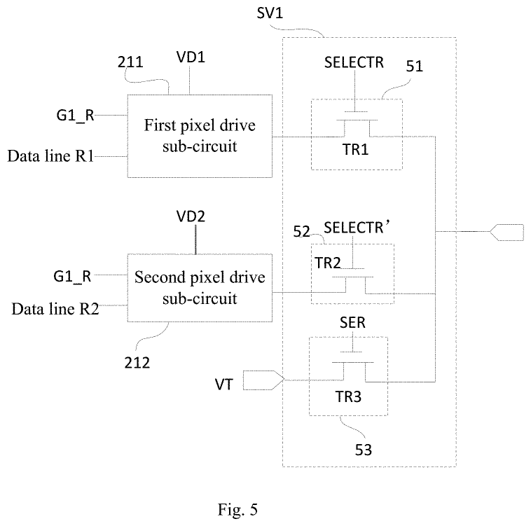

When n is equal to 1 and M is equal to 2, as shown in FIG. 5, the first voltage selector SV1 may include a first selective switch circuit 51, a second selective switch circuit 52 and a third selective switch circuit 53, on the basis of the embodiment of the drive sub-circuit shown in FIG. 2;

the selection control terminal of the first voltage selector SV1 includes a first red selection control terminal SELECTR, a second red selection control terminal SELECTR′ and a third red selection control terminal SER;

the first selective switch circuit 51 may include a first red switch transistor TR1; the second selective switch circuit 52 may include a second red switch transistor TR2; the third selective switch circuit 53 may include a third red switch transistor TR3;

a gate electrode of the TR1 is connected with the SELECTR, a drain electrode of the TR1 is connected with a first drive voltage output terminal of the first pixel drive sub-circuit 211, and a source electrode of the TR1 is connected with the first electrode layer; the first pixel drive sub-circuit 211 outputs the first drive voltage VD1 via the first drive voltage output terminal;

the gate electrode of the TR2 is connected with the SELECTR′, the drain electrode of the TR2 is connected with a second drive voltage output terminal of the second pixel drive sub-circuit 212, and the source electrode of the TR2 is connected with the first electrode layer; the first pixel drive sub-circuit 212 outputs the second drive voltage VD2 via the second drive voltage output terminal; and

the gate electrode of the TR3 is connected with the SER, the drain electrode of the TR3 is connected with the predetermined drive voltage terminal VT, and the source electrode of the TR3 is connected with the first electrode layer.

In an embodiment shown in FIG. 5, TR1, TR2, and TR3 are N-type thin film transistors, but are not limited thereto.

In operation of an embodiment of the drive sub-circuit, as shown in FIG. 5, when SELECTR outputs a high level, SELECTR′ outputs a low level and SER outputs a low level, TR1 is turned on, TR2 and TR3 are turned off, and the first pixel drive sub-circuit 211 can output VD1 to the first electrode layer;

when the SELECTR outputs a low level, the SELECTR′ outputs a high level, and the SER outputs a low level, the TR2 is turned on, the TR1 and the TR3 are turned off, and the second pixel drive sub-circuit 212 can output VD2 to the first electrode layer;

when the SELECTR outputs a low level, the SELECTR′ outputs a low level, and the SER outputs a high level, the TR3 is turned on, the TR1 and the TR2 are turned off, and the predetermined drive voltage terminal VT can output the predetermined drive voltage to the first electrode layer.

According to some embodiments of the present disclosure, the drive circuit includes N drive sub-circuits described above;

an n^{th} drive sub-circuit is connected with an n^{th} electrode layer included in a light-emitting circuit for supplying a corresponding drive voltage for the n^{th} electrode layer; and

n is a positive integer less than or equal to N, and N is an integer greater than 1.

Specifically, the drive circuit of some embodiments of the present disclosure may further include a voltage supply unit;

wherein the voltage supply unit is connected with an (N+1)^{th} electrode layer included in the light-emitting circuit for supplying the corresponding drive voltage to the (N+1)^{th} electrode layer.

Optionally, the drive voltage supplied by the voltage supply unit to the (N+1)^{th} electrode layer may be 0 V, a negative voltage or a high voltage, but is not limited thereto; also, the drive voltage supplied to the (N+1)^{th} electrode layer by the voltage supply unit may be a fixed voltage or may vary.

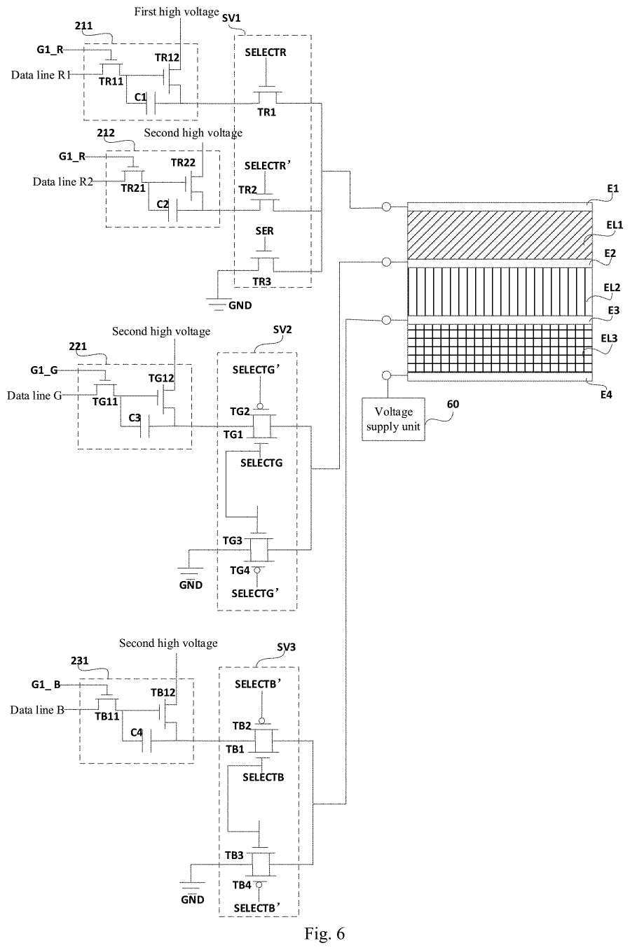

As shown in FIG. 6, some embodiments of the drive circuits described in some embodiments of the present disclosure are used to provide a respective drive voltage for each electrode layer in an embodiment of the light-emitting circuit shown in FIG. 1;

the drive circuit includes a first drive sub-circuit, a second drive sub-circuit, a third drive sub-circuit and a voltage supply unit 60;

the first drive sub-circuit includes a first pixel drive sub-circuit 211, a second pixel drive sub-circuit 212, and a first voltage selector SV1;

the first pixel drive sub-circuit 211 includes a first data writing transistor TR11, a first drive transistor TR12 and a first storage capacitor C1;

a gate electrode of the TR11 is connected with a first gate line G1_R, a drain electrode of the TR11 is connected with a first red data voltage VDATA_RH on a first data line Dataline R1, and a source electrode of the TR11 is connected with a gate electrode of the TR12;

a drain electrode of the TR12 is connected with a first high voltage V_HIGH, and a source electrode of the TR12 is connected with the first voltage selector SV1;

a first terminal of the C1 is connected with the gate electrode of the TR12, and a second terminal of the C1 is connected with the source electrode of the TR12;

the TR11 and the TR12 are both N-type thin film transistors;

the second pixel drive sub-circuit 212 includes a second data writing transistor TR21, a second drive transistor TR22 and a second storage capacitor C2;

a gate electrode of the TR21 is connected with the first gate line G1_R, a drain electrode of the TR21 is connected with a second red data voltage VDATA_RL on a second data line DataLine R2, and a source electrode of the TR21 is connected with a gate electrode of the TR22;

a drain electrode of the TR22 is connected with a second high voltage V_Middle, and a source electrode of the TR22 is connected with the first voltage selector SV1;

a first terminal of the C2 is connected with the gate electrode of the TR22, and a second terminal of the C2 is connected with the source electrode of the TR22;

the TR21 and the TR22 are both N-type thin film transistors;

the first voltage selector SV1 includes a first selective switch circuit, a second selective switch circuit and a third selective switch circuit;

the first selective switch circuit includes a first red switch transistor TR1; the second selective switch circuit includes a second red switch transistor TR2; the third selective switch circuit includes a third red switch transistor TR3;

a gate electrode of the TR1 is connected with a first red selection control terminal SELECTR, a drain electrode of the TR1 is connected with a source electrode of the TR22, and a source electrode of the TR1 is connected with the first electrode layer E1;

the gate electrode of the TR2 is connected with a second red selection control terminal SELECTR′, the drain electrode of the TR2 is connected with the source electrode of the TR22, and the source electrode of the TR2 is connected with the first electrode layer E1;

the gate electrode of the TR3 is connected with the third red selection control terminal SER, the drain electrode of the TR3 is connected with a ground terminal GND, and the source electrode of the TR3 is connected with the first electrode layer E1;

the TR1, the TR2 and the TR3 are all N-type thin film transistors;

the second drive sub-circuit includes a third pixel drive sub-circuit 221 and a second voltage selector SV2;

the third pixel drive sub-circuit 221 includes a third data writing transistor TG11, a third drive transistor TG11 and a third storage capacitor C3;

the gate electrode of the TG11 is connected with the second gate line G1_G, the drain electrode of the TG11 is connected with a green data voltage VDATA_G on a third data line DataLine G, and the source electrode of the TG11 is connected with the gate electrode of the TG12;

the drain electrode of the TG12 is connected with the second high voltage V_Middle, and the source electrode of the TG12 is connected with the second voltage selector SV2;

the first terminal of the C3 is connected with the gate electrode of the TG12, and the second terminal of the C3 is connected with the source electrode of the TG12;

the TG11 and the TG12 are N-type thin film transistors;

the second voltage selector SV2 includes a fourth selective switch circuit and a fifth selective switch circuit;

the fourth selective switch circuit includes a first green switch transistor TG1 and a second green switch transistor TG2; the fifth selective switch circuit includes a third green switch transistor TG3 and a fourth green switch transistor TG4;

the gate electrode of the TG1 is connected with a first green selection control terminal SELECTG, the drain electrode of TG1 is connected with the source electrode of the TG12, and the source electrode of the TG1 is connected with the second electrode layer E2;

the gate electrode of the TG2 is connected with a second green selection control terminal SELECTG′, the drain electrode of the TG2 is connected with the source electrode of the TG12, and the source electrode of the TG2 is connected with the second electrode layer E2;

the gate electrode of the TG3 is connected with the first green selection control terminal SELECTG, the drain electrode of the TG3 is connected with the ground terminal GND, and the source electrode of the TG3 is connected with the second electrode layer E2;

the gate electrode of the TG4 is connected with the second green selection control terminal SELECTG′, the drain electrode of the TG4 is connected with the ground terminal GND, and the source electrode of the TG4 is connected with the second electrode layer E2;

the TG1 and the TG3 are N-type thin film transistors, the TG2 and the TG4 are P-type thin film transistors;

the third drive sub-circuit includes a fourth pixel drive sub-circuit 231 and a third voltage selector SV3;

the third pixel drive sub-circuit 231 includes a fourth data writing transistor TB11, a fourth drive transistor TB12 and a fourth storage capacitor C4;

the gate electrode of the TB11 is connected with a third gate line G1_B, the drain electrode of the TB11 is connected with a blue data voltage VDATA_B on a fourth data line DataLine B, and the source electrode of the TB11 is connected with the gate electrode of the TB12;

the drain electrode of the TB12 is connected with the second high voltage V_Middle, and the source electrode of the TB12 is connected with the third voltage selector SV3;

the first terminal of the C4 is connected with the gate electrode of the TB12, and the second terminal of the C4 is connected with the source electrode of the TB12;

the TB11 and the TB12 are both N-type thin film transistors;

the third voltage selector SV3 includes a sixth selective switch circuit and a seventh selective switch circuit;

the sixth selective switch circuit includes a first blue switch transistor TB1 and a second blue switch transistor TB2; the seventh selective switch circuit includes a third blue switch transistor TB3 and a fourth blue switch transistor TB4;

the gate electrode of the TB1 is connected with a first blue selection control terminal SELECTB, the drain electrode of the TB1 is connected with the source electrode of the TB12, and the source electrode of the TB1 is connected with the third electrode layer E3;

the gate electrode of the TB2 is connected with a second blue selection control terminal SELECTB′, the drain electrode of the TB2 is connected with the source electrode of the TB12, and the source electrode of the TB2 is connected with the third electrode layer E3;

the gate electrode of the TB3 is connected with the first blue selection control terminal SELECTB, the drain electrode of the TB3 is connected with the ground terminal GND, and the source electrode of the TB3 is connected with the third electrode layer E3;

the gate electrode of the TB4 is connected with the second blue selection control terminal SELECTB′, the drain electrode of the TB4 is connected with the ground terminal GND, and the source electrode of the TB4 is connected with the third electrode layer E3;

the TB1 and the TB3 are N-type thin film transistors, and the TB2 and the TB4 are P-type thin film transistors; and

the voltage supply unit 60 is used for supplying a grounding voltage to the fourth electrode layer E4.

Some embodiments of the drive circuit in FIG. 6 and the embodiments of the light-emitting circuit in FIG. 1 constitute some embodiments of the pixel circuit.

Some embodiments of the pixel circuit shown in FIG. 6 are operative as follows:

when E1 is connected with V_Middle, and E2, E3 and E4 are grounded, the light-emitting circuit emits red light;

when the E2 is connected with V_Middle, and the E1, the E3 and the E4 are grounded, the light-emitting circuit emits green light;

when the E3 is connected with V_Middle, and the E1, the E2 and the E4 are grounded, the light-emitting circuit emits blue light;

when the E1 is connected with V_HIGH, the E2 is connected with V_Middle, and the E3 and the E4 are grounded, the light-emitting circuit emits yellow light;

when the E1 and the E3 are connected with V_Middle, and the E2 and the E4 are grounded, the light-emitting circuit emits fuchsia light;

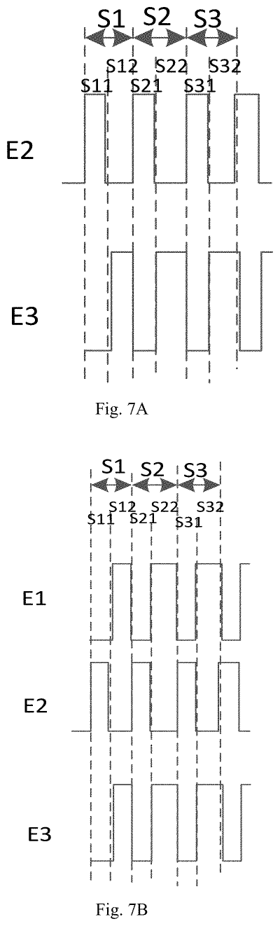

when the E1 and the E4 are grounded, the E2 is connected with the drive voltage and the E3 is connected with the drive voltage as shown in FIG. 7A, the light-emitting circuit emits dark green light; and

when the E4 is grounded, the E1 is connected with the drive voltage, the E2 is connected with the drive voltage, and the E3 is connected with the drive voltage as shown in FIG. 7B, the light-emitting circuit emits white light.

As shown in FIG. 7A, E2 is connected with the second high voltage and a low voltage at intervals, and the E3 is connected with the low voltage and the second high voltage at intervals;

as shown in FIG. 7B, E1 is connected with the low voltage and the second high voltage at intervals, the E2 is connected with the second high voltage and the low voltage at intervals, and the E3 is connected with the low voltage and the second high voltage at intervals; and

the low voltage may be, but is not limited to, a grounding voltage.

When some embodiments of the pixel circuit display dark green light, the light-emitting stage can be divided into a plurality of light-emitting sub-stages which are sequentially provided, wherein the light-emitting sub-stages include a first light-emitting time period and a second light-emitting time period which are sequentially provided, blue light is displayed in the first light-emitting time period, and green light is displayed in the second light-emitting time period, so that dark green is displayed by color mixing from switching the drive voltage at a high speed.

When some embodiments of the pixel circuit display white light, light-emitting layers of three colors need to emit light, so that the light-emitting stage is divided into a plurality of light-emitting sub-stages which are sequentially provided, wherein the light-emitting sub-stages include a first light-emitting time period and a second light-emitting time period which are sequentially provided, green is displayed in the first light-emitting time period, and red and blue are displayed in the second light-emitting time period, so that white is displayed by color mixing from switching the drive voltage at a high speed.

As shown in FIG. 7A, the light-emitting stage includes a first light-emitting sub-stage S1, a second light-emitting sub-stage S2 and a third light-emitting sub-stage S3 which are sequentially provided;

the first light-emitting time period included in the first light-emitting sub-stage S1 is indicated as S11, and the second light-emitting time period included in the first light-emitting sub-stage S1 is indicated as S12; the first light-emitting time period included in the second light-emitting sub-stage S2 is indicated as S21, and the second light-emitting time period included in the second light-emitting sub-stage S2 is indicated as S22; the first light-emitting time period included in the third light-emitting sub-stage S3 is indicated as S31, and the second light-emitting time period included in the third light-emitting sub-stage S3 is indicated as S32;

in S11, S21 and S31, and the E2 are connected with the second high voltage, and the E3 is connected with the low voltage; in S12, S22 and S32, and E2 are connected with the low voltage, and the E2 is connected with the second high voltage; and during the light-emitting stage, the E1 and the E4 are connected with the low voltage to emit dark green light.

As shown in FIG. 7B, the light-emitting stage includes a first light-emitting sub-stage S1, a second light-emitting sub-stage S2 and a third light-emitting sub-stage S3 which are sequentially provided;

the first light-emitting time period included in the first light-emitting sub-stage S1 is indicated as S11, and the second light-emitting time period included in the first light-emitting sub-stage S1 is indicated as S12; the first light-emitting time period included in the second light-emitting sub-stage S2 is indicated as S21, and the second light-emitting time period included in the second light-emitting sub-stage S2 is indicated as S22; the first light-emitting time period included in the third light-emitting sub-stage S3 is indicated as S31, and the second light-emitting time period included in the third light-emitting sub-stage S3 is indicated as S32;

in S11, S21 and S31, the E1 are connected with a low voltage, the E2 is connected with the second high voltage, and E3 is connected with the low voltage; in S12, S22 and S32, and the E1 are connected with the second high voltage, the E2 is connected with the low voltage, and the E2 is connected with the second high voltage; during the light-emitting stage, the E4 is connected with the low voltage to emit white light.

FIG. 7A and FIG. 7B are only used for examples, and in actual operation, the number of light-emitting sub-stages included in the light-emitting stage may be any integer greater than 1.

By adopting the drive circuit of some embodiments of the present disclosure and the pixel circuit of the light-emitting circuit of some embodiments of the present disclosure, organic light-emitting devices of three primary colors are made in the same pixel, the voltage of each electrode layer is changed by the voltage selector, and the luminance of the light-emitting layer of each color is adjusted by the voltage.

By cooperation of the pixel drive sub-circuit and the voltage selector, the drive circuit of some embodiments of the present disclosure and the pixel circuit of the light-emitting circuit of some embodiments of the present disclosure are adopted for controlling the voltage of each electrode layer to achieve the effect of displaying full color, the color of the pixel drive sub-circuit can be exchanged, and the structure of the pixel drive sub-circuit and the structure of each voltage selector are not limited to the structures in the above embodiments.

According to the drive circuit of some embodiments of the present disclosure and the pixel circuit of the light-emitting circuit of some embodiments of the present disclosure, in order to achieve the purpose of high resolution, novel pixels can be placed on the arrangement of traditional sub-pixels; and since the novel pixels can display full color, the horizontal resolution is improved by three (3) times and the resolution is rapidly increased under the limitation of the same process.

The pixel circuit adopting the drive circuit in some embodiments of the present disclosure and the light-emitting circuit in some embodiments of the present disclosure adopts a novel pixel arrangement design, and integrates three colors into a single pixel. Therefore, there is no concept of sub-pixels, and each pixel has a full-color display function. Under the design of the same resolution ratio, the novel pixel arrangement can increase the light-emitting area and effectively improve the device life of an Organic Light-Emitting Diode (OLED) because the minimum space limit between the sub-pixels is reduced.

The display panel of some embodiments of the present disclosure includes the light-emitting circuit described above.

The display device according to some embodiments of the present disclosure includes the drive circuit described above.

The display device provided by some embodiments of the disclosure can be any product or component with a display function, such as a mobile phone, a tablet computer, a television, a display, a notebook computer, a digital photo frame, a navigator and the like.

While the above mentioned is some embodiments of the present disclosure, it will be appreciated by those skilled in the art that various changes and modifications may be made without departing from the principle of the disclosure, and such changes and modifications should be considered within the scope of this disclosure

1. A light-emitting circuit, comprising N light-emitting layers and N+1 electrode layers, wherein the N light-emitting layers and the N+1 electrode layers are arranged in a laminated manner, and an n^{th} light-emitting layer is provided between an n^{th} electrode layer and an (n+1)^{th} electrode layer; and
N is an integer greater than 1, and n is a positive integer less than or equal to N.

2. The light-emitting circuit according to claim 1, wherein colors of the N light-emitting layers are different from each other.

3. The light-emitting circuit according to claim 1, wherein N is equal to 3;
the first light-emitting layer is a red light-emitting layer, the second light-emitting layer is a green light-emitting layer, and the third light-emitting layer is a blue light-emitting layer;
the first light-emitting layer is a red light-emitting layer, the second light-emitting layer is a blue light-emitting layer, and the third light-emitting layer is a green light-emitting layer;
the first light-emitting layer is a green light-emitting layer, the second light-emitting layer is a red light-emitting layer, and the third light-emitting layer is a blue light-emitting layer;
the first light-emitting layer is a green light-emitting layer, the second light-emitting layer is a blue light-emitting layer, and the third light-emitting layer is a red light-emitting layer;
the first light-emitting layer is a blue light-emitting layer, the second light-emitting layer is a green light-emitting layer, and the third light-emitting layer is a red light-emitting layer; or
the first light-emitting layer is a blue light-emitting layer, the second light-emitting layer is a red light-emitting layer, and the third light-emitting layer is a green light-emitting layer.

4. The light-emitting circuit according to claim 1, wherein the N light-emitting layers and the N+1 electrode layers are alternately arranged.

5. The light-emitting circuit according to claim 4, comprising three light-emitting layers and four electrode layers,
wherein the three light-emitting layers are respectively a first light-emitting layer, a second light-emitting layer and a third light-emitting layer; the four electrode layers are respectively a first electrode layer, a second electrode layer, a third electrode layer and a fourth electrode layer;
wherein the first electrode layer, the first light-emitting layer and the second electrode layer form a first light-emitting sub-circuit for emitting light of a first color;
the second electrode layer, the second light-emitting layer and the third electrode layer form a second light-emitting sub-circuit for emitting light of a second color; and
the third electrode layer, the third light-emitting layer and the fourth electrode layer form a third light-emitting sub-circuit for emitting light of a third color.

6. An illumining method of a light-emitting circuit applied to the light-emitting circuit according to claim 1, the illumining method of the light-emitting circuit comprising:
respectively providing corresponding drive voltages for N+1 electrode layers to illumine the light-emitting circuit during a light-emitting stage.

7. The illumining method of the light-emitting circuit according to claim 6, wherein the first light-emitting layer is a red light-emitting layer, the second light-emitting layer is a green light-emitting layer, and the third light-emitting layer is a blue light-emitting layer;
the illumining method of the light-emitting circuit, during the light-emitting stage, comprising:
controlling a drive voltage supplied to the first electrode layer to be a first high voltage, controlling the drive voltage supplied to the second electrode layer to be a second high voltage, and controlling the drive voltage supplied to the third electrode layer and the drive voltage supplied to the fourth electrode layer to be a low voltage, so that the light-emitting circuit emits yellow light;
controlling the drive voltage supplied to the first electrode layer to be a second high voltage, and controlling the drive voltage supplied to the second electrode layer, the drive voltage supplied to the third electrode layer and the drive voltage supplied to the fourth electrode layer to be a low voltage, so that the light-emitting circuit emits red light;
controlling the drive voltage supplied to the second electrode layer to be a second high voltage, controlling the drive voltage supplied to the first electrode layer, the drive voltage supplied to the third electrode layer and the drive voltage supplied to the fourth electrode layer to be a low voltage, so that the light-emitting circuit emits green light;
controlling the drive voltage supplied to the third electrode layer to be a second high voltage, controlling the drive voltage supplied to the first electrode layer, the drive voltage supplied to the second electrode layer and the drive voltage supplied to the fourth electrode layer to be a low voltage, so that the light-emitting circuit emits blue light; or
controlling the drive voltage supplied to the first electrode layer and the drive voltage supplied to the third electrode layer to be a second high voltage, and controlling the drive voltage supplied to the second electrode layer and the drive voltage supplied to the fourth electrode layer to be a low voltage, so that the light-emitting circuit emits fuchsia light.

8. The illumining method of the light-emitting circuit according to claim 6, wherein the first light-emitting layer is a red light-emitting layer, the second light-emitting layer is a green light-emitting layer, and the third light-emitting layer is a blue light-emitting layer;
the light-emitting stage comprises a plurality of light-emitting sub-stages which are sequentially provided; the light-emitting sub-stage comprises a first light-emitting time period and a second light-emitting time period which are sequentially provided;
the illumining method of the lighting circuit comprising:
controlling the drive voltage supplied to the first electrode layer and the drive voltage supplied to the fourth electrode layer to be a low voltage during the light-emitting stage; controlling the drive voltage supplied to the second electrode layer to be a second high voltage and controlling the drive voltage to the third electrode layer to be a low voltage during the first light-emitting time period; controlling the drive voltage supplied to the second electrode layer to be a low voltage and controlling the drive voltage supplied to the third electrode layer to be a second high voltage during the second light-emitting time period so as to control the light-emitting circuit to emit dark green light; or
controlling the drive voltage supplied to the fourth electrode layer to be a low voltage during the light-emitting stage; controlling the drive voltage supplied to the first electrode layer to be a low voltage, controlling the drive voltage supplied to the second electrode layer to be a second high voltage, and controlling the drive voltage to the third electrode layer to be a low voltage during the first light-emitting time period; and controlling the drive voltage supplied to the first electrode layer to be a high voltage, controlling the drive voltage supplied to the second electrode layer to be a low voltage and controlling the drive voltage supplied to the third electrode layer to be a second high voltage during the second light-emitting time period so as to control the light-emitting circuit to emit white light.

9. A drive sub-circuit for supplying a drive voltage to an n^{th} electrode layer in the light-emitting circuit according to claim 1, comprising a voltage selector and M pixel drive sub-circuits, wherein M is a positive integer;
the m^{th} pixel drive sub-circuit is used for controlling to output an m^{th} drive voltage to the voltage selector under the control of a gate drive signal input by a corresponding gate line and an m^{th} data voltage on an m^{th} data line; m is a positive integer less than or equal to M; and
the voltage selector is used for controlling a drive voltage supplied by one pixel drive sub-circuit or a predetermined drive voltage input by a predetermined drive voltage terminal to be provided to the n^{th} electrode layer under the control of a selection control signal input by a selection control terminal of the voltage selector.

10. The drive sub-circuit according to claim 9, wherein the m^{th} pixel drive sub-circuit comprises an m^{th} drive module, an m^{th} data writing module, and an m^{th} energy storage module,
wherein a control terminal of the m^{th} data writing module is connected with the corresponding gate line, a first terminal of the m^{th} data writing module is connected with the m^{th} data line, a second terminal of the m^{th} data writing module is connected with the control terminal of the m^{th} drive module, and the m^{th} data writing module is used for controlling the m^{th} data voltage to be written into the control terminal of the m^{th} drive module under the control of the gate drive signal;
the m^{th} drive module is used for controlling the m^{th} drive voltage to be outputted to the voltage selector under the control of the potential of the control terminal of the m^{th} drive module; and
the m^{th} energy storage module is connected with the control terminal of the m^{th} drive module for maintaining the potential of the control terminal of the m^{th} drive module.

11. The drive sub-circuit according to claim 9, wherein the voltage selector comprises M+1 selective switch circuits;
the m^{th} selective switch circuit is used for controlling the m^{th} drive voltage supplied by the m^{th} pixel drive sub-circuit to be provided to the n^{th} electrode layer under the control of the selection control signal input by the selection control terminal; and
the (M+1)^{th} selective switch circuit is used for controlling the predetermined drive voltage input by the predetermined drive voltage terminal to be provided to the n^{th} electrode layer under the control of the selection control signal input by the selection control terminal.

12. A drive circuit, comprising N drive sub-circuits according to claim 9;
wherein an n^{th} drive sub-circuit is connected with an n^{th} electrode layer included in a light-emitting circuit for supplying a corresponding drive voltage for the n^{th} electrode layer; and
n is a positive integer less than or equal to N, and N is an integer greater than 1.

13. The drive circuit according to claim 12, further comprising a voltage supply unit;
wherein the voltage supply unit is connected with an (N+1)^{th} electrode layer included in the light-emitting circuit for supplying the corresponding drive voltage to the (N+1)^{th} electrode layer.

14. A display panel, comprising the light-emitting circuit according to claim 1.

15. A display device, comprising the drive circuit according to claim 12.

16. The display panel according to claim 14, wherein the display panel is an Organic light-emitting Diode (OLED) display panel.

17. The light-emitting circuit according to claim 2, wherein N is equal to 3;
the first light-emitting layer is a red light-emitting layer, the second light-emitting layer is a green light-emitting layer, and the third light-emitting layer is a blue light-emitting layer;
the first light-emitting layer is a red light-emitting layer, the second light-emitting layer is a blue light-emitting layer, and the third light-emitting layer is a green light-emitting layer;
the first light-emitting layer is a green light-emitting layer, the second light-emitting layer is a red light-emitting layer, and the third light-emitting layer is a blue light-emitting layer;
the first light-emitting layer is a green light-emitting layer, the second light-emitting layer is a blue light-emitting layer, and the third light-emitting layer is a red light-emitting layer;
the first light-emitting layer is a blue light-emitting layer, the second light-emitting layer is a green light-emitting layer, and the third light-emitting layer is a red light-emitting layer; or
the first light-emitting layer is a blue light-emitting layer, the second light-emitting layer is a red light-emitting layer, and the third light-emitting layer is a green light-emitting layer.

18. The drive sub-circuit according to claim 10, wherein the voltage selector comprises M+1 selective switch circuits;
the m^{th} selective switch circuit is used for controlling the m^{th} drive voltage supplied by the m^{th} pixel drive sub-circuit to be provided to the n^{th} electrode layer under the control of the selection control signal input by the selection control terminal; and
the (M+1)^{th} selective switch circuit is used for controlling the predetermined drive voltage input by the predetermined drive voltage terminal to be provided to the n^{th} electrode layer under the control of the selection control signal input by the selection control terminal.

19. A display device, comprising the drive circuit according to claim 13.

20. The light-emitting circuit according to claim 1, wherein a luminance magnitude of each of the N light-emitting layers is adjusted by changing a voltage of each of the N+1 electrode layers.
